(19) United States
(12) Patent Application Publication
(10) Pub. No.: US 2009/0014063 A1
(43) Pub. Date: Jan. 15, 2009

(54) METHOD FOR PRODUCTION OF A SINGLE-SIDED CONTACT SOLAR CELL AND SINGLE-SIDED CONTACT SOLAR CELL

(75) Inventors: Rolf Stangl, Berlin (DE); Marinus Kunst, Berlin (DE); Klaus Lips, Berlin (DE); Manfred Schmidt, Berlin (DE); Jens Schneider, Leipzig (DE); Frank Wuensch, Berlin (DE)

Correspondence Address: DARBY & DARBY P.C., P.O. BOX 770, Church Street Station, New York, NY, 10008-0770, US

(73) Assignee: HAHN-MEITNER-INSTITUT BERLIN GMBH, Berlin (DE)

(21) Appl. No.: 11/915,984

(22) PCT Filed: May 22, 2006
(86) PCT No.: PCT/DE06/00917

§ 371 Date: Nov. 29, 2007

(30) Foreign Application Priority Data
May 29, 2005 (DE) 10 2005 025 125.0

(51) Int. Cl. H01L 31/06; H01L 31/18; H01L 31/042

(52) U.S. Cl. 136/256; 438/64; 438/98; 136/244

(57) ABSTRACT

A single-side contacted solar cell and method for production of a single-side contacted solar cell provide a direct arrangement of a contact grid on one side of an absorber layer. A free surface of the contact grid is coated with an electrically non-conducting insulation layer. An emitter layer is deposited on a whole surface such that the contact grid is arranged between the absorber layer and the emitter layer. The emitter layer is provided with a contact layer. For back face contact, the emitter layer is arranged on a back face of the absorber layer to avoid additional absorptive losses.

### CROSS REFERENCE TO RELATED APPLICATIONS

This is a U.S. national phase application under 35 U.S.C. § 371 of International Patent Application No. PCT/DE2006/000917, filed May 22, 2006, and claims benefit of German Patent Application No. 10 2005 025 125.0, filed May 29, 2005. The Internation Application was published in German on Dec. 7, 2006 as WO 2006/128427 A2 under PCT Article 21(2).

The present invention relates to a method of fabricating a single-side contacted solar cell having at least one absorber layer and one emitter layer of semiconductor materials.

### BACKGROUND

Solar cells are components which convert light into electrical energy. They are typically made of semiconductor materials which contain regions or layers of different conductivity for positive and negative charge carriers, n-type or p-type conductive regions. The regions are referred to as emitters and absorbers. Positive and negative excess charge carriers produced by incident light are separated at the pn junction between the emitter and absorber and can be collected and drained away by contacting systems which are electroconductively connected to the particular regions. Accordingly, only those excess charge carriers which reach the contacting systems and do not recombine beforehand in the particular case with an oppositely poled charge carrier, contribute to the useful electric power of solar cells.

In single-side contacted solar cells, both contacting systems used for separately collecting the excess majority and minority charge carriers of the absorber layer, are located on one common side. In the first case, the fundamental advantage is derived that only one side needs to be processed for contacting purposes, while the other side remains unprocessed with respect to contacting. Along the lines of the present invention, the term “front-side contacting” is employed when both contacting systems are located on the front side and thus on the side of the solar cell that faces the light during later use. On the other hand, the term “back-side contacting” is employed when both contacting systems are located on the back side and thus on the side of the solar cell that faces away from the light during later use. However, when configuring the contacting systems, the primary consideration is the charge carrier collection efficiency thereof. If the electronic quality of the absorber layer of the solar cell is adequate, i.e., if the effective diffusion length of the minority charge carriers is greater than the absorber layer thickness, then the contacting systems which drain away current should typically be located on the side of the solar cell that faces away from the light during later use (back-side contacting). In this case, one derives the advantages in particular therefrom that, in the first place, no shadowing losses are caused by a contacting system, thereby improving the efficiency of the solar cell. Secondly, a good, simple, full-surface-area passivation of the front side of the solar cell is achievable, so that the excess charges are able to be effectively and simply prevented from recombining at the front side. However, if the absorber layer has a relatively low electronic quality, i.e., if the effective diffusion length of the minority charge carriers is smaller than the absorber layer thickness, then the contacting systems which drain away current should advantageously be located on the front side of the solar cell (front-side contacting). All of the minority charge carriers of the absorber that are generated at a depth that is smaller than the effective diffusion length of the absorber can then be reliably collected. In comparison to the then unavoidable, disadvantageous shadowing caused by at least one contacting system, the single-side, front-side contacting offers a significant advantage in a technologically very simple contacting process which, in particular, does not include any back-side contacting and, thus, for example, does not require any patterning of the absorber or emitter layer in the thin-layer deposition.

Hardly any single-side, front-side contacted solar cells have been implemented due to the lack of a technologically simple and efficient production method. It is generally single-side, back-side contactings that are known. In this context, it is necessary to ensure that the first contacting system for collecting the majority charge carriers from the absorber layer be reliably electrically isolated from the second contacting system for collecting the minority charge carriers from the absorber layer. To that end, different concepts for producing and designing single-side, back-side contacted solar cells are known.

One conceptual design of the back-side contacting provides for utilizing surface elevations, as described, for example, in German Patent Application DE 41 43 083 A1. In this context, the first and second contacting systems are arranged directly on a substrate surface having elevations or on an insulation layer on the same formed, for example, in a pyramid, conical or cylindrical shape), the elevations having been covered beforehand, at least in some regions, with passivation material and subsequently uncovered therefrom in sections to permit attachment of the contacting systems. In addition, an inversion layer for draining away the minority charge carriers of the absorber layer extends along the substrate surface between the contacting systems. German Patent Application DE 41 43 084 A1 describes first passivating the entire patterned substrate surface and to subsequently remove the passivation layer again in the region of the elevations.

Finally, German Patent Application DE 101 42 481 A1 describes configuring these elevations in the form of ribs on the bottom side of the active semiconductor substrate and to provide a contacting system for each rib flank using directed vapor deposition. Thus, this concept is directed, in part, to always producing elevations on the bottom side of the substrate which are then processed in different ways.

Another concept pertaining to back-side contacting is point contacting (PC). It provides for keeping the two contacting systems on the back side very small in size in the form of points, in order to lower the reverse saturation current and thereby increase the open-circuit voltage of the solar cell. An extremely good surface passivation plays a decisive role in this case, however. U.S. Pat. No. 5,468,652 describes a point contacting where contact is made with the second contacting system on the bottom side of the substrate through holes that are laser-drilled through the emitter layer, which is arranged on the front side of the absorber layer, and that are laser-drilled through the absorber layer. In this context, the second contacting system is arranged in an interleaved configuration with the first contacting system to permit the majority charge carriers of the absorber layer to be drained away. World Patent Application WO 03/019674 A1 describes a point contacting is where different sized contact hole diameters are arranged symmetrically in rectangular regions. German Patent Application DE 198 54 269 A1, describes a point-contact solar cell where the second contacting system for collecting the minority charge carriers from the absorber layer is configured in a grid form and is arranged directly on the back side of the absorber layer in front of an electrically conductive substrate. The first contacting system for collecting the majority carriers from the absorber layer is formed over the entire surface area and is arranged on the back side of an electrically conductive substrate. The second contacting system between the absorber layer and the substrate is electrically isolated on both sides. The connection to the emitter layer is provided, in turn, by bores through the emitter and absorber layers which, as contact holes, are filled with a metal. The electrical contacting of the second contacting system is carried out via bridge circuits arranged laterally to the solar cell. Thus, patterning method steps are also required in the case of point contacting.

The same holds for the third concept of the interdigital solar cell (interdigitated back contact IBC) having a back-side contacting, where the first and second contacting systems are likewise arranged in an interleaved, comb-type configuration on the back substrate side, as is described in U.S. Pat. No. 4,927,770, U.S. Patent Application 2004/0200520 A1, German Patent DE 195 25 720 C2 and German Patent Application DE 100 45 246 A1. In contrast to the point-contact solar cell, however, the emitter layer is not configured to traverse to the front side of the absorber layer facing the light during use, but rather is disposed in small subregions on the back side facing away from the light during use. There, it alternates with subregions having the same, but heavier doping than the absorber layer, to form a minority charge-carrier backscattering back surface field (BSF). Therefore, in this concept, the patterning measures extend to the forming of the emitter layer. Electrically isolating the different subregions from one another poses a significant problem.

A wafer-based, back-side contacted crystalline homo-solar cell is described in World Patent Application DE 696 31 815 T2 which provides for the emitter layer to be patterned by counterdoping the absorber layer. The counterdoping is carried out using dopants from a contact grid. In this context, a contact system in the form of a contact grid is placed on the emitter layer, wrapped by an insulation layer, and covered by the other contact system. Thus, the two contact systems rest directly one over the other, separated only by an insulation layer. The emitter is not designed as an independent functional layer, but rather formed as small integrated regions in the semiconductor material (crystalline silicon) of the absorber layer in a counterdoping process; thus, it is a homo-solar cell. The insulation layer on the metal grid can be formed by employing a self-aligning technique, for example by using a selective oxide, such as aluminum oxide. The deeply penetrating emitter regions are formed under the action of high temperature by diffusing parts of the metal grid and forming an alloy in the semiconductor material (counterdoping) on the back side in the semiconductor material of the absorber layer, respectively in a BSF layer diffused-in beforehand on the back side. Thus, the contact grid is always located on the emitter regions. Because of the counterdoping, it is not possible for a sharp pn junction to be formed between two oppositely doped semiconductor layers. The diffusion processes for the counterdoping require high temperatures and are difficult to control. All of this limits the efficiency of the known homo-solar cells.

German Patent Application DE 198 19 200 A1 describes a single-side front-side contacting where the emitter layer and both contacting systems have a finger-shaped structure. It also describes a single-side contacting fashioned by the etch-patterning of trenches or holes and the application of metallizations using shadow masks. German Patent Application DE 197 15 138 A1 describes solar cells having a front side contacting to be connected in series by patterning both contacting systems and the emitter layer by electroconductively connecting the land structures of the comb-type contacting systems to one another accordingly.

### SUMMARY

It is an aspect of the present invention to provide a method for fabricating a single-side contacted solar cell that does not require any complex patterning measures for the contacting systems or for the individual solar cell layers and that is simple to implement. Another aspect of the present invention is to provide a reliably functioning solar cell that features an effective electrical isolation of the two contacting systems and a highest possible efficiency.

In an embodiment, the present invention provides a method of fabricating a single-side contacted solar cell. The single-side contacted solar cell includes at least one absorber layer and one emitter layer. The absorber layer and the emitter layer include semiconductor materials. The absorber layer has one of a p- or n-type doping. The emitter layer has one of a p- or n-type doping that is the opposite type doping as the doping of the absorber layer. The p- or n-type doping of the absorber and emitter layers is deposited over an entire surface of each of the absorber the emitter layers. Excess majority and minority charge carriers produced in the absorber layer by light incidence are separated at a pn junction between the absorber and emitter layers. The majority charge carriers are collected and drained away from the absorber layer via a contacting system. The minority charge carriers are collected and drained away from the absorber layer by the emitter layer and a another contacting system. Both contacting systems residing on the same side of the solar cell, the method comprising the steps of: The method includes a step of providing an unpatterned absorber layer. The method further includes the step of applying a first contacting system in the form of a contact grid to a first side of the absorber layer. The contact grid is surface-area optimized such that it collects majority charge carriers. The method further includes the step of providing, over an entire exposed surface of the contact grid, an electrically non-conductive insulation layer that is configured to prevent charge carriers from tunneling therethrough. The method further includes the step of depositing an emitter layer in a layer thickness such that minority charge carriers reach a side of the emitter layer facing away from the absorber layer without suffering appreciable ohmic losses. The emitter layer including a semiconductor material that defines a pn junction relative to the absorber layer. The pn junction passivating at a maximum boundary surface recombination rate of excess charge carriers of 10⁵ recombinations/cm²s. The method further includes the step of applying a second contacting system as a planar contact layer to a side of the emitter layer facing away from the absorber layer. The method further includes the step of electrically contacting the contact grid and the contact layer.

In another embodiment, the present invention provides a single-side contacted solar cell. The single-side contacted solar cell includes at least one absorber layer and an emitter layer. The absorber layer and the emitter layer include a semiconductor material. The absorber layer has one of a p- or n-type doping. The emitter layer has one of a p- or n-type doping that is the opposite type doping as the doping of the absorber layer. The p- or n-type doping of the absorber and emitter layers are deposited over an entire surface of each of the absorber the emitter layers. Excess majority and minority charge carriers produced in the absorber layer by light incidence are separated at a pn junction between the absorber and emitter layers. The majority charge carriers are collected and drained away from the absorber layer via a first contacting system. The minority charge carriers are collected and drained away from the absorber layer by the emitter layer and a second contacting system. Both the first and second contacting systems reside on a same side of the solar cell. The first contacting system is a contact grid that is surface-area optimized such that it collects the majority charge carriers and is electrically isolated from the emitter layer by an insulation layer. The insulation layer prevents charge carriers from tunneling therethrough and is disposed between the absorber layer and the emitter layer. The second contacting system is a planar contact layer arranged on a side of the emitter layer facing away from the absorber layer. The emitter layer is made of a semiconductor material that defines a pn junction relative to the absorber layer. A pn junction passivates at a maximum boundary surface recombination rate of the excess charge carriers of 10⁵ recombinations/cm²s.

### BRIEF DESCRIPTION OF THE DRAWINGS

Aspects of the present invention will now be described by way of exemplary embodiments with reference to the following drawings, in which:

FIG. 1 is a schematic flow diagram of a method for fabricating a single-side contacted solar cell according to an exemplary embodiment of the present invention;

FIG. 2 is a cross-section view of a back-side contacted solar cell according to an exemplary embodiment of the present invention;

FIG. 3 is a cross-section view of a front-side contacted solar cell according to an exemplary embodiment of the present invention; and

FIG. 4 is a plan view of a modular interconnection of a plurality of single-side contacted solar cells according to an exemplary embodiment of the present invention.

### DETAILED DESCRIPTION

By employing the method according to the present invention, a single-side contacting is achieved, without requiring patterning of the absorber or emitter layer in the process. To that end, the first contacting system in the form of a contact grid is placed directly on one side of the absorber layer, thereby forming an effective ohmic contact. In the process, the contact area of the contact grid relative to the absorber layer is dimensioned in such a way that it is able to optimally conduct away the anticipated current. To that end, the total surface area of the contact grid is typically less than 5% of the absorber surface area. An insulation layer is subsequently applied to the contract grid over the entire exposed surface thereof not contacted by the absorber layer, to electrically isolate the same. In this context, this insulation layer has at least such a minimum layer thickness that charge carriers are also safely prevented from tunneling through. Different methods for applying the insulation layer are presented further below. The electrical contacting of the contact grid may be accomplished by providing laterally configured land structures or by recessing (using a shadow mask, for example) a connection region on the contact grid during deposition of the emitter layer, and exposing the connection region by removing (for example mechanically scraping off) the subsequently formed insulation layer.

Once the contact grid has been electrically isolated, the emitter layer is applied to the contact grid over the entire surface, with the result that the contact grid resides between the absorber and emitter layers. In the process, the layer thickness of the applied emitter layer is dimensioned in such a way that the minority charge carriers of the absorber layer may reach the back side of the emitter layer facing away from the absorber layer without suffering any appreciable ohmic losses in the process. In particular, a thin emitter layer may also be applied. Thus, depending on the layer thickness of the emitter layer and contract grid, either a continuous, full-surface-area emitter layer (layer thickness of the emitter layer is greater than that of the contact grid and insulation layer) which completely covers the contact grid, or, however, a discontinuous emitter layer (the layer thickness of the emitter layer is smaller than the layer thickness of the contact grid and insulation layer) which does not completely cover the contact grid may be provided. This kind of emitter layer discontinuity is not due to a complex structuring, but rather is the result of a simple, full-surface-area emitter deposition that necessarily follows from the layer thickness selection. In addition, the emitter layer is made of a material that enables a readily passivated pn junction to be defined relative to the absorber layer, it being necessary to meet a maximum boundary surface recombination rate of the charge carriers of 10⁵ recombinations/cm²/s. The aim, however, is to achieve a boundary surface recombination rate of 10² recombinations/cm²/s, for example. Specific embodiments of the emitter layer are described further below.

In a method according to an exemplary embodiment of the present invention, the second contacting system for conducting the minority charge carriers of the absorber layer away from the emitter layer is subsequently placed as an unpatterned contact layer on the back side of the emitter layer, thereby forming an effective ohmic contact.

In this context, the contact layer may be formed over the entire surface or, using a mask technique, over part of the surface, and be applied in a simple manner, for example by applying a metal contact or by using vapor deposition. Since it is directly accessible, the contact layer may be electrically contacted directly without requiring further measures.

A method according to an exemplary embodiment of the present invention is suited in the same way for manufacturing a single-sided front-side or back-side contacting of a solar cell. As already explained above, the selection of the single-sided contacting is dependent on the electronic quality of the absorber layer. If this quality is good, preference is to be given to a back-side contacting, due to fewer shadowing losses. However, if the electronic quality is poor, preference should be given to a front-side contacting.

A back-side contacting is achieved when a method step II (see below)—applying the contact grid to collect the majority charge carriers of the absorber layer—is carried out on the back side of the absorber layer. In this context, the emitter layer is also arranged on the back side of the absorber layer, whereby the normally occurring absorption losses are avoided by arranging an emitter layer on the front side of the absorber layer. Since, at this point, the absorber layer is no longer passivated on the front side by the emitter layer, an additional method step A (see below) following a method step I (see below)—preparation of the absorber layer—provides for the absorber layer to be passivated there by a corresponding transparent overlayer. In this context, the passivating overlayer, which, for example, may be made of silicon oxide or silicon nitride, is used both for reducing the surface recombination (by directly passivating the surface defects or by forming a minority charge-carrier backscattering front surface field FSF), as well as for reducing the incident reflected light, since it is formed as an antireflection coating.

A front-side contacting is accomplished when method step II is carried out on the front side of the absorber layer. Accordingly, in the context of the front-side contacting, the contact layer that conducts the minority charge carriers of the absorber layer away from the emitter layer and is likewise arranged on the later light-incidence side, is to be implemented as a transparent layer, for example in the form of a transparent conductive oxide layer TCO. The electronic quality of the absorber layer (method step B) determines, in turn, whether an overlayer is to be applied to the back side thereof. If this quality is good, a passivation layer is necessary to avoid charge carrier recombination. In some instances, a reflection coating may also be needed to reflect unabsorbed photons. On the other hand, if the electronic quality of the absorber layer is poor, the minority charge carriers do not reach the back side of the absorber layer, obviating the need in this case for any further measures. Therefore, since the back side of the absorber layer does not require any passivating overlayer, very defective starting layers (seed layers) may be used, for example, to grow the absorber layer and/or reflection coatings for reflecting the unabsorbed photons. To improve the process of collecting charge carriers on the front side, another method step C may be provided following method step V—application of the contact layer. In this case, it is a question of applying a contact element to the front side of the transparent contact layer. To minimize the shadowing losses, it is advantageous for the contact element and contact grid to have a congruent design and be directly positioned one over the other.

The contact grid—also subsumed under the term “grid” are finger shapes or similar shapes—may be applied in prefabricated form directly to the absorber layer using a conductive adhesive, for example. In addition, the contact grid may be selectively applied directly to the absorber layer in a simple screen printing process or by thermal vaporization of an electrically conductive material using an appropriate mask. The use of ink jet printing or photolithography is likewise possible.

To prevent the minority charge carriers from recombining undesirably underneath the contact grid, an additional method step F may be provided subsequently to method step II—application of the contact grid to the absorber layer. In this case, it is a question of annealing the conductive material, for example aluminum, from the contact grid into the subjacent absorber layer, for example p-doped silicon, to form a back-side passivation field (back surface field BSF, alneal process). In particular, this thermal step may be combined with the thermal step for forming an electrically isolated insulation layer on the contact grid (see the next paragraph).

To apply the insulation layer to the exposed surface of the contact grid in accordance with method step III, an insulating compound may be selectively applied, for example, using screen or ink-jet printing, or a mask, in particular through the use of a shadow mask, or sputtering, vapor phase deposition or photolithography. Alternatively, an oxide layer may also be thermally, wet-chemically or electrochemically grown (method step D) over the entire exposed surface of the contact grid and the back side of the absorber layer. In this case, a different oxide layer forms due to different materials selected for the contact grid and the absorber layer. In the case of a contact grid of aluminum, for example, aluminum oxide accordingly; in the case of an absorber layer of silicon when an oxygen annealing process is used, thermal silicon oxide. In the example of an oxygen annealing process, when working with the aluminum contact grid system on the silicon absorber layer, one may expect an approximately 20 nm thick aluminum oxide on the entire exposed surfaces of the contact grid, and an approximately 5 nm thick silicon oxide on the surface of the absorber layer not covered by the contact grid. When the oxide layer is thermally produced, this process may be carried out together with method step F—annealing the conductive material of the contact grid into the absorber layer to form a BSF—in a temperature-controlled heating process.

The subsequent selective etching of the oxide layer on the absorber layer (method step E) is to be easily performed accordingly, since the different oxides typically have different etch rates in the etching process. In particular, given a properly selected etching medium, a metal oxide is more etch-resistant than a silicon oxide. In the example of aluminum and silicon material, which is then used accordingly for the emitter layer as well, the selective etching may be realized, for example, by a simple short-term immersion into dilute hydrofluoric acid. In this case, the hydrofluoric acid not only selectively removes the silicon oxide, but, at the same time, ensures an effective surface passivation of the absorber layer of silicon by forming Si—H bonds. Thus, the etchant may be selected in such a way that, following removal of the oxide from the absorber layer, this layer is effectively passivated at the exposed surface thereof.

Frequently when working with hetero solar cells, buffer layers are used between the emitter and absorber layer in order to more effectively passivate the boundary surface between the emitter and absorber. Therefore, it may be beneficial when a further optional method step G is provided subsequently to method step III—producing the insulation layer on the contact grid. It is a question in this case, accordingly, of the optional, full-surface-area deposition of a buffer layer in the smallest possible layer thickness. In the case of doped amorphous silicon as emitter material on a crystalline silicon wafer as absorber, the buffer layer may be an ultrathin (approximately 5 nm) layer of intrinsic (undoped) amorphous silicon, for example. Buffer layers may also be formed from a salt, for example from cesium chloride. A corresponding surface dipole is then defined, and the boundary surface recombination is likewise suppressed at the pn junction.

Using the previously described method according to the present invention, a highly efficient solar cell may be produced both as a thick-layered cell based on a wafer as absorber layer, as well as a thin-layered cell having a laminar structure grown on a substrate or superstrate and provided with an exclusively single-side contacting. It should be noted that when a self-supporting wafer is used as an absorber layer, any given processing of the two sides may be carried out. On the other hand, a thin-layered structure always requires a sequential processing, beginning with the substrate (incident light first through the functional layers) or superstrate (incident light first through the superstrate), since the thin absorber layer is not load-bearing. Therefore, there may be a variation in the method step sequence depending on whether a wafer solar cell or a thin-layered solar cell is being produced. Generally, however, the individual method steps are retained unchanged. Thus, a solar cell according to the present invention is fundamentally characterized in that, as a first contacting system, a contact grid that is surface-area optimized for collecting the majority charge carriers of the absorber layer and is electrically isolated from the emitter layer by an insulation layer, is arranged between the absorber layer and the emitter layer, and, as a second contacting system, a planar contact layer is arranged on the side of the emitter layer facing away from the absorber layer, the emitter layer being made of a semiconductor material which, relative to the absorber layer, defines a pn junction that passivates at a maximum boundary surface recombination rate of the excess charge carriers of 10⁵ recombinations/cm²s. A solar cell that is back-side contacted in this manner also features a novel layered structure geometry since it has a traversing emitter layer on the back side of the absorber layer.

The absorber and emitter layers may preferably be made of silicon. In this context, a hetero-contact solar cell may be produced when crystalline silicon, in particular having n- or p-type doping (n/p c-Si), is used for the absorber layer and amorphous, hydrogen-enriched silicon, accordingly having p- or n-type doping (p/n a-Si:H), is used for the emitter layer. An optionally present buffer layer between the absorber and emitter layers may likewise be preferably made of amorphous, though undoped, silicon. A material system of this kind ensures an especially well passivated pn junction for the purpose of charge separation. In this case, in the context of a back-side contacting, all of the contacting systems may be made of aluminum. In the case of a front-side contacting, the contact layer must be made of a transparent conductive material. For the sake of avoiding repetitive explanations, with regard to other specific embodiments of the single-side contacted solar cell according to the present invention, reference is made to the special specification section.

The method for producing a single-side contacted solar cell may likewise be employed for fabricating a front-side, as well as a back-side contacting. In this context, front side OSZ of solar cell SZ is defined in the following as the side provided in later operation for light incidence, and back side OSA of solar cell SZ as the side of solar cell SZ that is not provided in later operation for light incidence. With regard to light incidence, this applies analogously to other components.

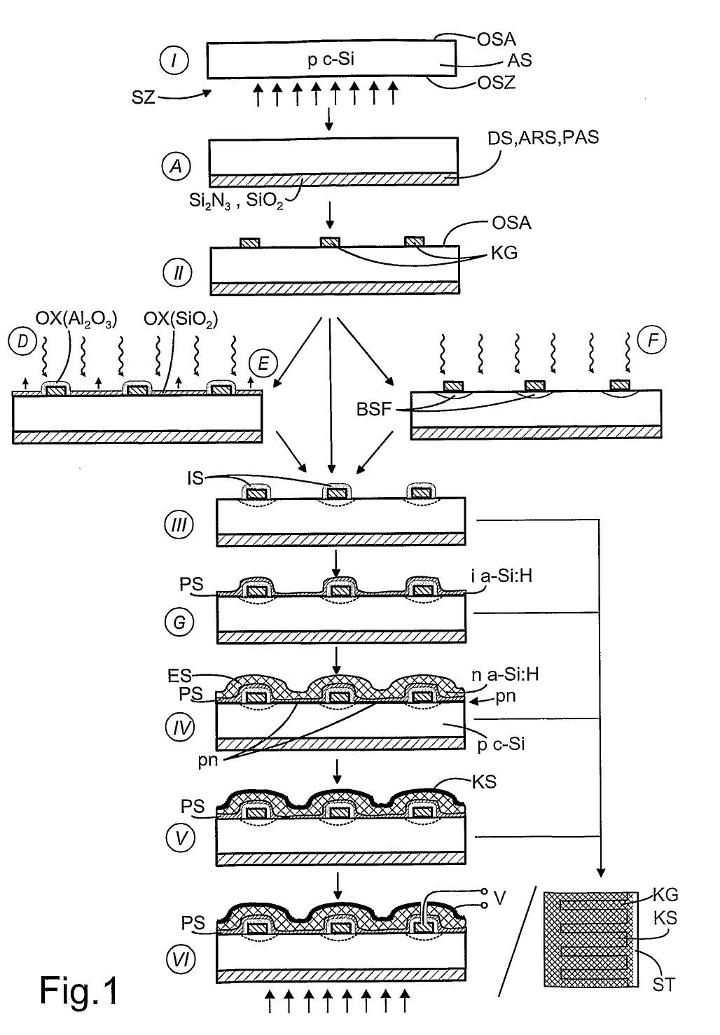

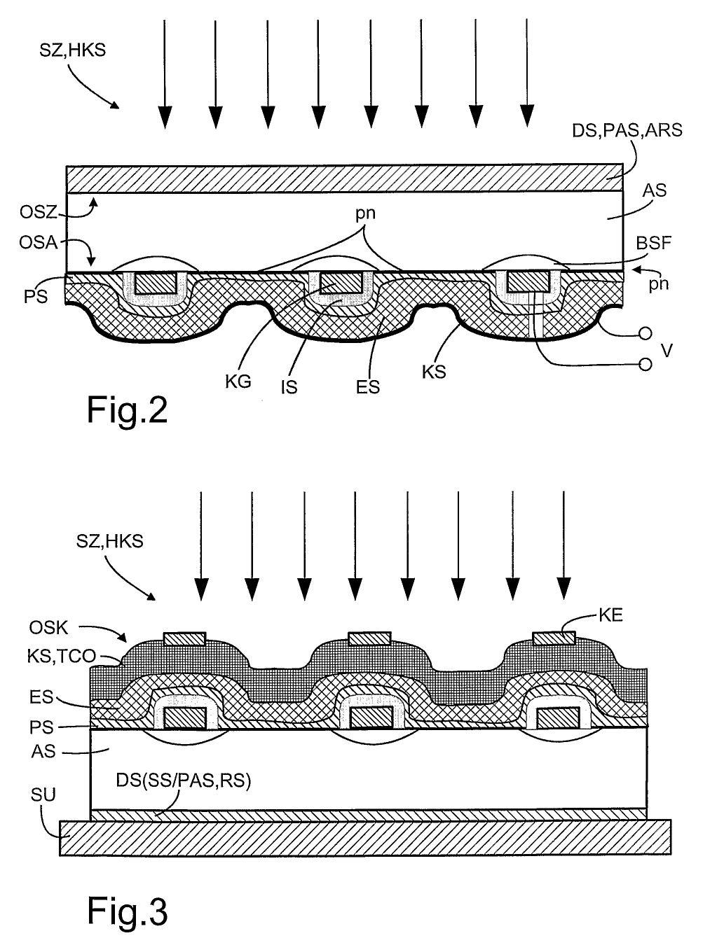

FIG. 1 clarifies the fabrication of a back-side contacted solar cell SZ with reference to a schematic flow diagram (the solar cell is shown in cross section). A front-side contacted solar cell is fabricated in an analogous manner. The presents exemplarily the production of a solar cell SZ that includes an absorber layer AS of crystalline silicon having p-type doping (p c-Si), an emitter layer ES of amorphous, hydrogen-enriched silicon having n-type doping (n a-Si:H), and aluminum for contact grid KG and contact layer KS. In this type of material selection, which allows solar cell SZ to be produced as hetero-contact solar cell HKS (compare FIG. 2) using a short-term annealing process in a manner known per se, the aluminum/silicon contact is able to form a charge-carrier backscattering local region BSF having highly p-doped silicon, thereby making it possible to minimize recombination at contact grid KG (alneal process).

Method Step I

Selection and preparation of a suitable absorber layer AS. This may be a silicon wafer, or also a thin silicon layer grown using thin film technology. It may preferably be crystalline silicon in p-type doping (p c-Si). The later incidence of light into front side OSZ of absorber layer AS, which faces the light, is indicated by arrows shown in FIG. 1 below absorber layer AS. Front side OSZ of the absorber layer may be textured as needed, in order to improve the trapping of light. This also holds true of a wafer-based solar cell with regard to back side OSA of the absorber layer.

Method Step A

Passivation of front side OSZ of absorber layer AS with an overlayer DS of silicon oxide or silicon nitride in accordance with a standard method. In this context, overlayer DS may have a dual function since, besides providing passivation (passivation layer PAS), it also reduces the reflection (antireflection coating ARS) of the incident light. It is likewise possible for two or more overlayers DS having separate functions to be applied.

Method Step II

Applying a contact grid KG of aluminum to back side OSA of absorber layer AS. Contact grid KG may be applied in a thermal vaporization process through a mask, a simple screen printing process, ink jet printing, or, however by photolithography.

Method Step F

Annealing (indicated in FIG. 1 by wiggly vertical arrows) of the aluminum of contact grid KG into absorber layer AS (alneal process). This results in the formation of charge-carrier backscattering local regions BSF underneath Al contact grid KG. If indicated, to produce the BSF, method step A may also be interchanged with method steps II and F. Method step F does, in fact, provide an option, however, for further enhancing the efficiency of solar cell SZ. Method step F may be implemented together with method step D in a shared heating process.

Method Step III

Producing an electrically non-conductive insulation layer IS on contact grid KG over the entire exposed surface thereof. In this context, insulation layer IS must have at least such a minimum layer thickness that charge carriers are safely prevented from tunneling through. This measures ensures that the two contacting systems are safely isolated from one another. Insulation layer IS may be produced in a simple manner by applying an insulating compound, for example in a screen or ink-jet printing process, using a mask technique, a sputtering process, vapor phase deposition or photolithography. Alternatively, however, an insulating oxide layer OX may also be produced in accordance with method step D (aluminum oxide Al₂O₃ and silicon oxide SiO₂), which provides then for the silicon oxide on absorber layer AS to be subsequently selectively removed again therefrom in accordance with method step E.

Method Step D

Oxidizing the surface of Al contact grid KG to a higher valency, for example by annealing the same in an oxygen atmosphere (indicated in FIG. 1 by wiggly vertical arrows). An approximately 30 nm thick aluminum oxide Al₂O₃ and an approximately 5 nm thick silicon oxide SiO₂ are then formed, at least when method step F is not implemented. It is likewise possible for oxide layer OX to be grown in a wet chemical or electrochemical process.

Method Step E

Selective etching of the silicon oxide (indicated in FIG. 1 by small, upward-pointing arrows) in the region of absorber layer AS, for example by immersion in dilute hydrofluoric acid (HF dip). Hydrofluoric acid readily etches silicon oxide, however, only marginally etches aluminum oxide, so that, upon immersion, the silicon oxide is removed only selectively. Moreover, if method step F is omitted, then the silicon oxide will be even thinner than the aluminum oxide. If silicon nitride is used as a passivating overlayer DS, then this is likewise inert to etching by hydrofluoric acid. If, on the other hand, thermal silicon oxide is used as overlayer DS, then the etching rate must be selected in such a way that, on the one hand, the silicon oxide is still retained on front side OSZ of absorber layer AS (approximately 200 nm); on the other hand, however, the silicon oxide is completely removed from back side OSA of absorber layer AS (approximately 5 nm). The HF dip not only removes the back-side silicon oxide, but also effectively passivates the silicon surface due to thereby forming Si—H bonds.

Method Step G

Optional, full-surface-area deposition of an ultrathin buffer layer PS; in the selected exemplary embodiment, intrinsic, hydrogenated, amorphous silicon i a-Si:H, for example through plasma-enhanced chemical vapor deposition (PECVD). In this context, the purpose of buffer layer PS is to passivate the boundary surface (pn junction) between absorber layer AS and emitter layer ES and thereby reduce recombination. For this purpose, it may be applied in the smallest possible layer thickness, for example 5 nm.

Method Step IV

Full-surface-area deposition of thin emitter layer ES, for example through plasma-enhanced chemical vapor deposition (PECVD) of a thin-layer emitter of n-doped, hydrogenated, amorphous silicon n a-Si:H. A deposition process using sputtering or thermal vaporization is likewise possible. Since thin (at a minimum, approximately 5 nm, to allow a pn junction to still be defined) emitter layer ES is located on back side OSA of absorber layer AS when forming a back-side contacting, it may be deposited as a thicker layer (for example, 50 nm instead of 5 nm), even without any appreciable recombination losses, and thereby ensure complete coverage of absorber layer AS, in spite of the comparatively large dimensions of contact grid KG (approximately 1 μm high). Such layer thickness ratios result in a discontinuity of emitter layer ES in the region of contact grid KG. However, this does not influence the method of functioning of solar cell SZ. The figures show a continuous, gap-free coverage of contact grid KG by emitter layer ES; thus, emitter layer ES is selected in these instances to be thicker than contact grid KG and insulation layer IS combined. Relative to absorber layer AS, emitter layer ES defines a pn junction that separates charge carriers. In this context, emitter layer ES has a maximum layer thickness that allows the charge carriers to reach side OSE of emitter layer ES facing away from the absorber layer, without suffering any appreciable ohmic losses.

Method Step V

Applying the second contacting system in the form of a planar contact layer KS to the back side of emitter layer ES facing away from the absorber layer. For example, a metallic contacting may be applied over the entire surface by thermal vaporization of aluminum.

Method Step VI

Contacting of contact grid KG and of contact layer KS. The unrestricted accessibility to contact layer KS readily permits electrical contacting thereof at any given location. Contact grid KG may be directly contacted by recessing a small region above contact grid KG when depositing emitter layer ES in accordance with method step IV and when vapor depositing back contact layer KS, in each case using a mask. Insulation layer IS is subsequently removed in this region (for example, by mechanical destruction of the same, such as by scraping the 30 nm thin aluminum oxide layer), thereby allowing an electrical lead wire to be advanced to contact grid KG.

Alternatively, on the exterior of the solar cell, contact grid KG may have a comb-type land structure ST, half of which is covered when emitter layer ES and contact layer KS are produced. Following removal of insulation layer IS, this land structure ST may then be electrically contacted (shown alternatively in method step VI to the right in FIG. 1).

Method Step H

Another method step H may also be optionally provided following method step IV: Cleaning the surface of absorber layer AS not covered by contact grid KG. In practice, however, the surface of absorber layer AS should always be cleaned, respectively bared (brief HF dip) shortly before the a-Si:H deposition of emitter layer ES to ensure an effective boundary surface passivation of absorber layer AS immediately prior to emitter deposition and thus to ensure a high level of efficiency for hetero-solar cell HKS. The HF dip then removes either the natural silicon oxide always present on a silicon surface that is stored for longer than 30 min. or, however, also the thermal/electrochemical silicon oxide formed by the process of insulating contact grid KG.

In FIG. 2, finish-processed solar cell SZ having a back-side contacting is shown in cross section (transversely to the contact fingers of contact grid KG) (the light incidence is illustrated by parallel arrows). Dual-function overlayer DS is disposed on front side OSZ of absorber layer AS. Contact grid KG for collecting the majority charge carriers from absorber layer AS is located on back side OSA of absorber layer AS. Charge-carrier backscattering fields BSF that reduce recombination losses are formed underneath contact grid KG in absorber layer AS. Contact grid KG is covered with an electrical insulation layer IS, preventing any short circuit to the subsequent full-surface-area emitter layer ES from occurring. A buffer layer PS may be optionally arranged between absorber layer AS and emitter layer ES. The charge carrier-separating pn junction is formed between emitter layer ES and absorber layer AS; the minority charge carriers of the absorber layer are driven into the emitter layer. Contact layer KS for collecting the charge carriers from emitter layer ES is applied to emitter layer ES over the entire surface thereof. The (for example metallic) contact layer KS is used at the same time as a reflector layer RS for the unabsorbed photons. The electrical contacting (voltage V) takes place between freely accessible contact layer KS and an exposed location of contact grid KG.

In FIG. 3, a finish-processed solar cell SZ having a front-side contacting is shown in cross section (transversely to the contact fingers of contact grid KG) (the light incidence is illustrated by parallel arrows). In this case, on front side OSZ of absorber layer AS, planar contact layer KS is formed as a transparent, conductive oxide layer TCO. The subjacent structure corresponds to that of solar cell SZ having back-side contacting in accordance with FIG. 2. In contrast thereto, in the case of the front-side contacted solar cell SZ in accordance with FIG. 3, an optional metallic contact element KE is arranged on front side OSK of transparent contact layer KS. This improves the collection and draining of the charge carriers since, depending on its layer thickness, a transparent, conductive oxide layer as contact layer KS is not as effective in the electrical conductivity thereof as a metallic contact layer KS. The thickness of TCO contact layer KS required for conducting away the current may be reduced by employing a contact element KE. To minimize shadowing, contact element KE may be designed and configured congruently to contact grid KG. It may be made of chromium/silver, for example, and is electrically contacted together with contact layer KS.

Moreover, in contrast to back-side contacted solar cell SZ, front-side contacted solar cell SZ does not require a passivation layer PAS on back side OSA of absorber layer AS when the electronic quality of the material of absorber layer AS is lower. Therefore, to allow optimized deposition of absorber layer AS, a seed layer SS may be provided, for example, as back-side overlayer DS on back side OSA of absorber layer AS. Seed layer SS may have been applied beforehand to a substrate SU. Moreover, besides a passivation layer PAS or a seed layer SS, an additional reflection coating RS that reflects the unabsorbed photons may be provided as overlayer DS.

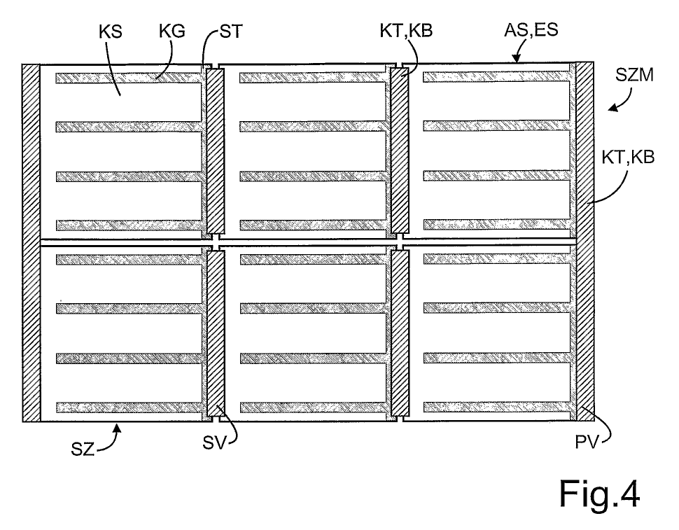

FIG. 4 shows an exemplary interconnection of a plurality of single-side contacted solar cells SZ in a shared solar cell module SZM (in a simplified back-side plan view facing away from the later incidence of light in the context of back-side contacting; the full-surface-area contact layer KS resides over contact grid KG, land structure ST of contact grid KG not being covered by contact layer KS, however). The concept of single-side contacted solar cell SZ presented here permits namely a technologically very simple series/parallel interconnection of individual solar cells SZ to form one solar cell module SZM. This interconnection is especially practical when crystalline silicon wafers are used to form absorber layer AS for solar cells SZ, since the series and parallel interconnection process may be substantially simplified by the single-side back-side contacting. If land structure ST of contact grid KG (compare FIG. 1, alternatively in method step VI) is placed at the edge of a square c-Si wafer being used as absorber layer AS, then contact layer KS covering emitter layer ES, and land structure ST of contact grid KG may be interconnected in series SV or in parallel PV in a simple manner through direct contacting KT, for example with the aid of a copper band KB.

FIG. 4 illustrates an interconnection of single-side, back-side contacted solar cells SZ. In the case of an interconnection of single-side, front-side contacted solar cells SZ, a slight difference in design is apparent in that land structures ST of contact grid KG and of contact element KE are not superposed, but rather are disposed in mutual opposition. Other interconnection methods, in particular those adapted to thin-film technology, are, of course, likewise possible.

### LIST OF REFERENCE NUMERALS

ARS antireflection coating
AS absorber layer
BSF charge-carrier backscattering field
DS overlayer
ES emitter layer
HKS hetero-contact solar cell
IS electrically non-conductive insulation layer
KB copper band
KE contact element
KG contact grid
KS contact layer
KT contacting
OSA back side of AS
OSE side of ES facing away from absorber layer
OSK front side of KS
OSZ front side of AS
OX electrically insulating oxide layer
PAS passivation layer
pn pn junction
PS buffer layer
PV parallel interconnection
RS reflection coating
SS seed layer
ST land structure
SU substrate
SV series interconnection
SZM solar cell module
SZ solar cell
TCO transparent, conductive oxide layer
V voltage

1-31. (canceled)

32. A method of fabricating a single-side contacted solar cell including at least one absorber layer and one emitter layer, the absorber layer and the emitter layer including semiconductor materials, the absorber layer having one of a p- or n-type doping, the emitter layer having one of a p- or n-type doping that is the opposite type doping as the doping of the absorber layer, the p- or n-type doping of the absorber and emitter layers deposited over an entire surface of each of the absorber the emitter layers, wherein excess majority and minority charge carriers produced in the absorber layer by light incidence are separated at a pn junction between the absorber and emitter layers, the majority charge carriers collected and drained away from the absorber layer via a contacting system, and the minority charge carriers are collected and drained away from the absorber layer by the emitter layer and a another contacting system, both contacting systems residing on the same side of the solar cell, the method comprising the steps of:
I. providing an unpatterned absorber layer;
II. applying a first contacting system in the form of a contact grid to a first side of the absorber layer, wherein the contact grid is surface-area optimized such that it collects majority charge carriers;
III. providing, over an entire exposed surface of the contact grid, an electrically non-conductive insulation layer configured to prevent charge carriers from tunneling therethrough;
IV. depositing an emitter layer in a layer thickness such that minority charge carriers reach a side of the emitter layer facing away from the absorber layer without suffering appreciable ohmic losses, the emitter layer including a semiconductor material that defines a pn junction relative to the absorber layer, the pn junction passivating at a maximum boundary surface recombination rate of excess charge carriers of 10⁵ recombinations/cm²s;
V. applying a second contacting system as a planar contact layer to a side of the emitter layer facing away from the absorber layer, and
VI. electrically contacting the contact grid and the contact layer.

33. The method recited in claim 32, wherein the first side of the absorber layer is a back side of the absorber layer, and further comprising a step:
providing a transparent overlayer on a front side of the absorber layer following step I, IV or V.

34. The method recited in claim 33, wherein the transparent overlayer is formed as a passivation layer and as an antireflection coating.

35. The method recited in claim 32, wherein the first side of the absorber layer is a front side of the absorber layer and wherein the contact layer of step II has a transparent form, and further comprising the step:
providing at least one overlayer on a back side of the absorber layer before or after step I, depending on an electronic quality of the absorber layer.

36. The method recited in claim 35, wherein at least one overlayer is at least one of a passivation layer, a reflection coating and a seed layer.

37. The method as recited in claim 35, further comprising the step:
applying to the front side of the transparent contact layer a contact element arranged congruently with the contact grid following step V and wherein in step VI, the contact element is electrically contacted together with the contact layer.

38. The method recited in claim 32, wherein step II is carried out by the selective application of an electrically conductive material in a thermal vaporization process with the aid of at least one of a mask, screen printing, ink jet printing and photolithography.

39. The method recited in claim 32, wherein step III is carried out by selectively applying an electrically insulating compound to the contact grid over the entire exposed surface thereof using at least one of thermal vaporization, sputtering and vapor phase deposition with the aid of at least one of a mask, screen printing, ink jet printing and photolithography.

40. The method recited in claim 32, wherein step III is carried out by at least one of thermally, wet-chemically and electrochemically growing an oxide layer on the contact grid and on locations not covered by the contact grid on the absorber layer, and by subsequently selectively etching the oxide layer on locations not covered by the contact grid on the absorber layer.

41. The method as recited in claim 32, wherein step VI is carried out by recessing a connection region on the contact grid during the deposition of the emitter layer in step IV, and by exposing the connection region by removing the insulation layer.

42. The method recited in claim 32, wherein step VI is carried out by at least one of thermal vaporization, sputtering and vapor phase deposition.

43. The method recited in claim 32, further comprising the step:
annealing the conductive material of the contact grid into the absorber layer following step II.

44. The method recited in claim 41, further comprising the step:
annealing the conductive material of the contact grid into the absorber layer, together with method step III so as to thermally grow an oxide layer.

45. The method recited in claim 32, further comprising the step:
depositing a buffer layer in a small layer thickness before step IV.

46. The method recited in claim 45, wherein the step of depositing a buffer layer in a small layer thickness is carried out by at least one of thermal vaporization, sputtering and vapor phase deposition.

47. The method recited in claim 32, further comprising the step:
cleaning a surface of the absorber layer not covered by the contact grid after step IV.

48. The method recited in claim 32, wherein at least one of mono-, multi- or polycrystalline and recrystallized silicon are used for the absorber layer, amorphous hydrogenated silicon is used for the buffer layer and the emitter layer, aluminum is used for the contact grid, and aluminum is used for the contact layer when implementing step II on a back side of the absorber layer or a transparent conductive oxide is used for the contact layer when implementing step II on a front side of the absorber layer.

49. The method recited in claim 32, wherein the absorber layer is formed as at least one of a wafer, a thin layer on a substrate and a superstrate, and when the absorber layer is formed as a substrate or superstrate the steps for depositing the layers carried out according to a thin-layer technology sequentially, beginning with the substrate or superstrate.

50. A single-side contacted solar cell, comprising:
at least one absorber layer; and
an emitter layer,
wherein the absorber layer and the emitter layer include a semiconductor material, the absorber layer having one of a p- or n-type doping, the emitter layer having one of a p- or n-type doping that is the opposite type doping as the doping of the absorber layer, the p- or n-type doping of the absorber and emitter layers deposited over an entire surface of each of the absorber the emitter layers,
wherein excess majority and minority charge carriers produced in the absorber layer by light incidence are separated at a pn junction between the absorber and emitter layers, the majority charge carriers collected and drained away from the absorber layer via a first contacting system, and the minority charge carriers are collected and drained away from the absorber layer by the emitter layer and a second contacting system, both the first and second contacting systems residing on a same side of the solar cell,
wherein, the first contacting system is a contact grid that is surface-area optimized such that it collects the majority charge carriers and is electrically isolated from the emitter layer by an insulation layer, the insulation layer preventing charge carriers from tunneling therethrough, the contact grid disposed between the absorber layer and the emitter layer, and the second contacting system is a planar contact layer disposed on a side of the emitter layer facing away from the absorber layer, the emitter layer made of a semiconductor material that defines the pn junction relative to the absorber layer, the pn junction passivating at a maximum boundary surface recombination rate of the excess charge carriers of 10⁵ recombinations/cm²s.

51. The single-side contacted solar cell recited in claim 50, wherein the contact grid is located on a back side of the absorber layer, and further comprising a transparent overlayer located on a front side of the absorber layer.

52. The single-side contacted solar cell recited in claim 51, wherein the transparent overlayer is formed as a passivation layer and as an antireflection coating.

53. The single-side contacted solar cell recited in claim 50, wherein the contact grid is located on the front side of the absorber layer and the contact layer is formed as a transparent layer and an overlayer is arranged on the back side of the absorber layer.

54. The single-side contacted solar cell recited in claim 52, wherein a contact clement is arranged congruent to the contact grid and on a front side of the transparent contact layer.

55. The single-side contacted solar cell recited in claim 53, wherein the overlayer is formed as at least one of a passivation layer, a reflection coating, and a seed layer.

56. The single-side contacted solar cell recited in claim 50, wherein a land structure is configured to electrically contact the contact grid and is configured on an edge side of the solar cell.

57. The single-side contacted solar cell recited in claim 56, wherein the land structure is configured for an electrical series or parallel interconnection of a plurality of solar cells in a solar cell module.

58. The single-side contacted solar cell recited in claim 50, wherein the emitter layer and the insulation layer include a hole configured to electrically contact the contact grid.

59. The single-side contacted solar cell recited in claim 50, further comprising a minority charge-carrier backscattering surface field disposed underneath the contact grid.

60. The single-side contacted solar cell recited in claim 50, further comprising a buffer layer having a small layer thickness disposed between the absorber layer and the emitter layer.

61. The single-side contacted solar cell recited in claim 50, wherein the absorber layer is formed as at least one of a wafer, a thin layer on a substrate and a superstrate.

62. The single-side contacted solar cell recited in claim 54, wherein the absorber layer including at least one of mono-, multi- or polycrystalline or recrystallized crystalline silicon having n- or p-type doping, the emitter layer including hydrogen-enriched amorphous silicon having p- or n-type doping, the buffer layer including hydrogen-enriched, undoped amorphous silicon, the insulation layer including aluminum oxide, the overlayer including silicon oxide or silicon nitride, the contact grid including aluminum, the contact layer is aluminum or transparent conductive oxide and the contact element is chromium or silver
